(19) United States
(12) Patent Application Publication
(10) Pub. No.: US 2022/0231008 A1
(43) Pub. Date: Jul. 21, 2022

(54) ELECTROSTATIC DISCHARGE PROTECTION DEVICE AND OPERATING METHOD

(71) Applicant: MACRONIX INTERNATIONAL CO., LTD., Hsinchu (TW)

(72) Inventors: Shih-Yu WANG, Taipei City (TW); Chih-Wei HSU, Changhua County (TW); Wen-Tsung HUANG, Changhua County (TW)

(21) Appl. No.: 17/151,707

(22) Filed: Jan. 19, 2021

(51) Int. Cl. H01L 27/02; H01L 29/74

(52) U.S. Cl. CPC H01L 27/0248; H01L 29/7436

(57) ABSTRACT

An ESD protection device includes a semiconductor substrate, a first well, a second well, a third well, a first doping region, a second doping region, a second doping region, a third doping region and a fourth doping region. The first well and the second well have a first conductivity, and the third well has a second conductivity. The first doping region having a first conductivity is disposed in the first well. The second doping region having a second conductivity is disposed in the third well, and the first and the second doping regions are isolated from each other. The third doping region and the fourth doping region have a first conductivity and a second conductivity, respectively. The second doping region and the third doping region are electrically coupled. The first well, the second well, the third well and the fourth doping region form a parasitic SCR.

### BACKGROUND OF THE INVENTION

### Field of the Invention

The invention relates in general to a semiconductor device, and more particularly to an electrostatic discharge (ESD) protection device and an operating method thereof.

### Description of the Related Art

An ESD event commonly results from the discharge of a high voltage potential and leads to pulses of high current in a short duration (typically, 100 nanoseconds). Semiconductor integrated circuit (IC) is vulnerable to ESD events resulted by human or machines contact with the leads of the IC, and thus ESD currents pass through the IC to make the component failure. Accordingly, an ESD protection circuit is essential to a semiconductor IC.

A parasitic silicon controlled rectifier (SCR) is one kind of on-chip semiconductor ESD protection device. SCR can be turned on by snapback when ESD zapping occurs, and conduct ESD current to the ground to achieve ESD protection, so that parasitic SCR have been recognized in the prior art as one of the most effective elements in semiconductor ESD protection circuits. However, once the parasitic SCR cannot be turned on smoothly, the current shunting capability will not be improved.

Therefore, there is a need of providing an improved ESD protection device and a method for operating the same to obviate the drawbacks encountered from the prior art.

### SUMMARY OF THE INVENTION

The present invention relates to an electrostatic discharge protection device and an operating method thereof, which can solve the problem that the conventional parasitic silicon controlled rectifier cannot be turned on smoothly, and can reduce the effective resistance of the electrostatic discharge protection device.

According to one aspect of the present invention, an electrostatic discharge protection device is provided, including a semiconductor substrate, a first well, a second well, a third well, a first doping region, a second doping region, a second doping region, a third doping region and a fourth doping region. The first well, the second well and the third well are disposed in the semiconductor substrate, and the third well is directly coupled to and disposed between the first well and the second well. The first well and the second well have a first conductivity, and the third well has a second conductivity. The first doping region having a first conductivity is disposed in the first well. The second doping region having a second conductivity is disposed in the third well, and the first doping region and the second doping region are isolated from each other. The third doping region and the fourth doping region have a first conductivity and a second conductivity, respectively, and are disposed in the second well and are isolated from each other. The second doping region and the third doping region are electrically coupled. The first well, the second well, the third well and the fourth doping region form a parasitic silicon controlled rectifier.

According to one aspect of the present invention, an operation method of an electrostatic discharge protection device is provided, which includes the following steps. An electrostatic discharge protection device is provided. The electrostatic discharge protection device is electrically connected to an internal circuit. The electrostatic discharge protection device includes a parasitic silicon controlled rectifier and a diode string connected to each other. When an electrostatic discharge stress is applied to the internal circuit, the electrostatic discharge protection device leads an electrostatic discharge current from one bonding pad to another bonding pad.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A is a schematic cross-sectional view of an ESD device according to an embodiment of the invention.

FIG. 1B is a schematic diagram of the equivalent circuit of the ESD device of FIG. 1A.

FIG. 2A is a schematic cross-sectional view of an ESD device according to another embodiment of the invention.

FIG. 2B is a schematic diagram of the equivalent circuit of the ESD device of FIG. 2A.

FIG. 3A is a schematic cross-sectional view of an ESD device according to another embodiment of the invention.

FIG. 3B is a schematic diagram of the equivalent circuit of the ESD device of FIG. 3A.

FIG. 4 is a schematic cross-sectional view of an ESD device according to a comparative example.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION OF THE INVENTION

Details are given in the non-limiting embodiments below. It should be noted that the embodiments are illustrative examples and are not to be construed as limitations to the claimed scope of the present invention. The same/similar denotations are used to represent the same/similar components in the description below.

### First Embodiment

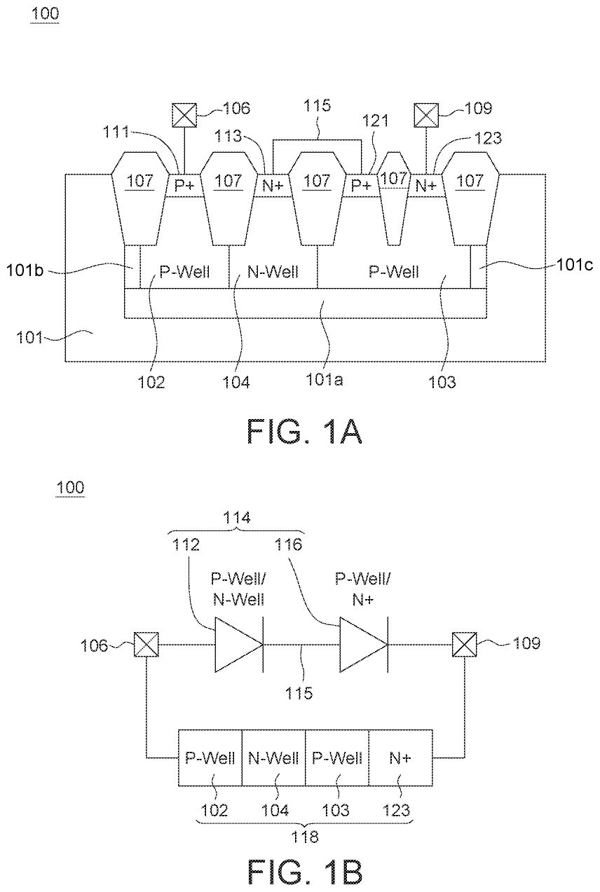

Please refer to FIGS. 1A and 1B, which respectively show a cross-sectional schematic diagram of an ESD device 100 and a schematic diagram of its equivalent circuit according to an embodiment of the invention.

According to an embodiment of the invention, the ESD device 100 includes a semiconductor substrate 101, a first well 102, a second well 103, a third well 104, a first doping region 111, a second doping region 113, a third doping region 121, and a fourth doping region 123.

In an embodiment, the semiconductor substrate 101 can be made of a suitable basic semiconductor (such as silicon (Si) or germanium (Ge) and so on), a compound semiconductor (such as silicon carbide (SiC), gallium arsenide (GaAs), gallium phosphide (GaP), iodine phosphide (IP), iodine arsenic (IAs) and/or iodine antimony (ISb)) or a combination thereof. The semiconductor substrate 101 is, for example, a P-type substrate. The semiconductor substrate 101 includes a first well 102 and a second well 103 with P-type conductivities, and a third well 104 with N-type conductivity, wherein the third well 104 connects to the first well 102 and the second well 103 and is disposed between the first well 102 and the second well 103. In addition, the semiconductor substrate 101 is separated from the first well 102, the second well 103, and the third well 104 by, for example, a deep N-well 101a. Furthermore, the semiconductor substrate 101 and the first well region 102 are separated by, for example, an N-well 101b, and the semiconductor substrate 101 and the second well region 103 are separated by, for example, an N-well 101c.

The first doping region 111 having P-type conductivity is disposed in the first well 102. The first doping region 111 (represented by P+) has a doping concentration greater than the doping concentration of the first well 102. The second doping region 113 having N-type conductivity is disposed in the third well 104. The second doping region 113 (represented by N+) has a doping concentration greater than the doping concentration of the third well 104. In an embodiment, each of the first doping region 111 and the second doping region 113 may have a doping concentration of 10¹⁵/cm². The first well 102 and the third well 104 may have a doping concentration of 10¹³/cm².

The first doping region 222 can be connected to the voltage source 105 via a bonding pad 106. During a normal operation (for example, the operating voltage is about 2V), the voltage can be applied to the first doping region 111 by the voltage source 105. A plurality of isolations 107 can be respectively disposed in the ESD device 100, and the isolations 107 are, for example, disposed between the first doping region 111 and the second doping region 113, between the second doping region 113 and the third doping region 121, and between the third doping region 121 and the fourth doping region 123 to perform the function of electrical isolation.

The third doping region 121 having P-type conductivity is disposed in the second well 103. The third doping region 121 (represented by P+) has a doping concentration greater than the doping concentration of the second well 103. The fourth doping region 123 having N-type conductivity is disposed in the second well 103. The fourth doping region 123 (represented by N+) has a doping concentration greater than the doping concentration of the second well 103. In an embodiment, each of the third doping region 121 and the fourth doping region 123 may have a doping concentration of 10¹⁵/cm², and the second well 103 may have a doping concentration of 10¹³/cm².

As shown in FIGS. 1A and 1B, the second doping region 113 and the third doping region 121 are electrically coupled by a metal wire 115. The first well 102 and the third well 104 are directly connected and contact each other to form a diode 112, the second well 103 and the fourth doping region 123 are directly connected and contact each other to form another diode 116, the two diodes are electrically coupled by a metal wire 115 to form a diode string 114. That is to say, the ESD current can flow into the diode string 114 from the bonding pad 106 through the first doping region 111, and then lead to the bonding pad 109 to protect the internal circuit of the integrated circuit from ESD damage.

In addition, referring to FIGS. 1A and 1B, the first well 102, the third well 104 and the second well 103 form a parasitic PNP bipolar junction transistor (BJT) circuit with P-type majority carriers. The third well 104, the second well 103 and the fourth doping region 123 form a parasitic NPN bipolar junction transistor circuit with N-type majority carriers. The collector of the PNP bipolar transistor is connected to the base of the NPN bipolar transistor; and the base of the PNP bipolar transistor is connected to the collector of the NPN bipolar transistor. The two parasitic circuits are connected to form a parasitic silicon controlled rectifier (SCR) 118 in the semiconductor substrate 101. In the ESD device 100, the first doping region 111 is the anode of the parasitic silicon controlled rectifier 118, and the fourth doping region 123 is the cathode of the parasitic silicon controlled rectifier 118.

In an embodiment, when ESD stress is applied to the internal circuit, the ESD stress flows through the two forward diodes 112 and 116 from the bonding pad 106 to the bonding pad 109. The bonding pad 106 is the base-emitter of the PNP bipolar transistor, and the bonding pad 109 is the base-emitter of the NPN bipolar transistor. When the bonding pads 106 and 109 are turned on in the forward direction, the parasitic silicon controlled rectifier 118 is turned on, so that electrons and holes are not generated by breakdown. Therefore, in addition to flowing into the diode string 114, the ESD current can also flow into the parasitic silicon controlled rectifier 118 via the first doping region 111 from the bonding pad 106, and lead to the bonding pad 109 via the fourth doping region 123.

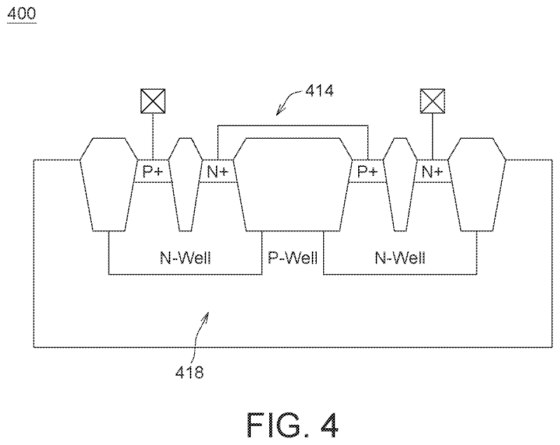

Referring to FIG. 4, which shows a schematic cross-sectional view of an ESD device 400 according to a comparative example. Compared with the first embodiment, the comparative example does not have the third well 104 coupled between the first well 102 and the second well 103, although a parasitic silicon controlled rectifier 418 (P+/N-well/P-well/N-well) can be formed in the semiconductor substrate of the comparative example, one of the diodes (P+/N-Well) is not the base-emitter of the NPN bipolar transistor (N-well/P-well/N-well) in the parasitic silicon controlled rectifier 418, when the diode string 414 is turned on, the parasitic silicon controlled rectifier 418 is unable to turn on normally. In this embodiment of the invention, a parasitic silicon controlled rectifier 118 (P-well/N-well/P-well/N+) is formed in the semiconductor substrate 101, and the parasitic silicon controlled rectifier 118 and the diode series 114 are connected in parallel to provide the ESD device 100 with two ESD paths to improve the current shunting capability, such that the effective circuit path of electrostatic discharge increases, and the effective resistance of the ESD device 100 is reduced. There is no need to provide another ESD protection component that takes up a larger layout space so as to reduce the overall layout size of the integrated circuit.

### Second Embodiment

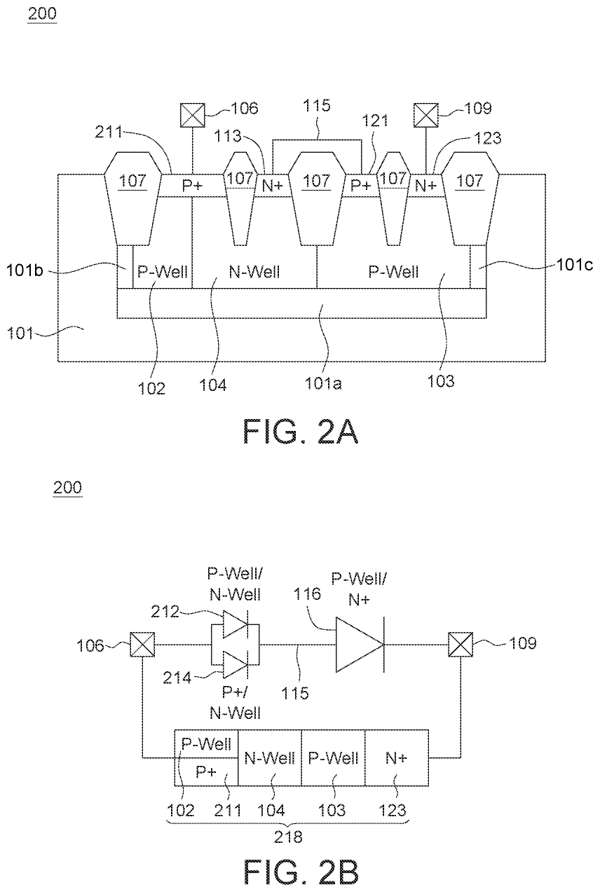

Please refer to FIGS. 2A and 2B, which respectively show a cross-sectional schematic diagram of an ESD device 200 and a schematic diagram of its equivalent circuit according to another embodiment of the invention. The structure of the ESD device 200 is analog to the structure of the ESD device 100 shown in FIG. 1A, except that a part of the first doping region 211 is disposed in the first well 102, and another part of the first doping region 211 is disposed in the third well 104. The first doping region 211 is analog to the first doping region 111.

In the ESD device 200, there are two diodes connected in parallel, in which the first well 102 and the third well 104 are coupled to form a diode 212, and the first doping region 211 and the third well 104 are coupled to form another diode 214, thereby the effective circuit path of ESD is increased.

In addition, when ESD stress is applied to the internal circuit protected by the ESD device 200, the ESD current can not only flow into the diode string 212, 214 and 116, but also can flow into the first well 102 and the third well 104 through the first doping region 211 from the bonding pad 106, respectively, in which the first well 102, the third well 104, the second well 103 and the fourth doping area 123 constitute a first shunt of a parasitic silicon controlled rectifier 218, and the first doping region 211, the third well 104, the second well 103 and the fourth doping region 123 constitute a second shunt of the parasitic silicon controlled rectifier 218. The first shunt and the second shunt are connected in parallel, such that the effective circuit path for ESD is increased, and then, the ESD current is led to the bonding pad 109 through the fourth doping region 123.

In this embodiment, the second shunt of the parasitic silicon controlled rectifier 218 includes a parasitic PNP bipolar transistor circuit formed by the first doping region 211, the third well 104, and the second well 103, and a parasitic NPN bipolar transistor circuit formed by the third well 104, the second well 103 and the fourth doping region 123. The collector of the PNP bipolar transistor is connected to the base of the NPN bipolar transistor parasitic circuit; and the base of the PNP bipolar transistor is connected to the collector of the NPN bipolar transistor parasitic circuit. The two parasitic circuits are connected to form a second shunt of the parasitic silicon controlled rectifier 218 in the semiconductor substrate 101 to improve the current shunting capability.

Referring to FIG. 4, compared with the second embodiment, the comparative example does not have the third well 104 coupled between the first well 102 and the second well 103, although a parasitic silicon controlled rectifier 418 (P+/N-well/P-well/N-well) can be formed in the semiconductor substrate of the comparative example, one of the diodes (P+/N-Well) is not the base-emitter of the NPN bipolar transistor (N-well/P-well/N-well) in the parasitic silicon controlled rectifier 418, when the diode string 414 is turned on, the parasitic silicon controlled rectifier 418 is unable to turn on normally. In this embodiment of the invention, a parasitic silicon controlled rectifier 218 having two shunting paths (P-well/N-well/P-well/N+ and P+/N-well/P-well/N+) is formed in the semiconductor substrate 101, and the parasitic silicon controlled rectifier 218 and the diode string 212, 214 and 116 are connected in parallel to provide the ESD device 200 with two or more ESD paths to improve the current shunting capability, such that the effective circuit path of electrostatic discharge increases, and the effective resistance of the ESD device 200 is reduced. There is no need to provide another ESD protection component that takes up a larger layout space so as to reduce the overall layout size of the integrated circuit.

### Third Embodiment

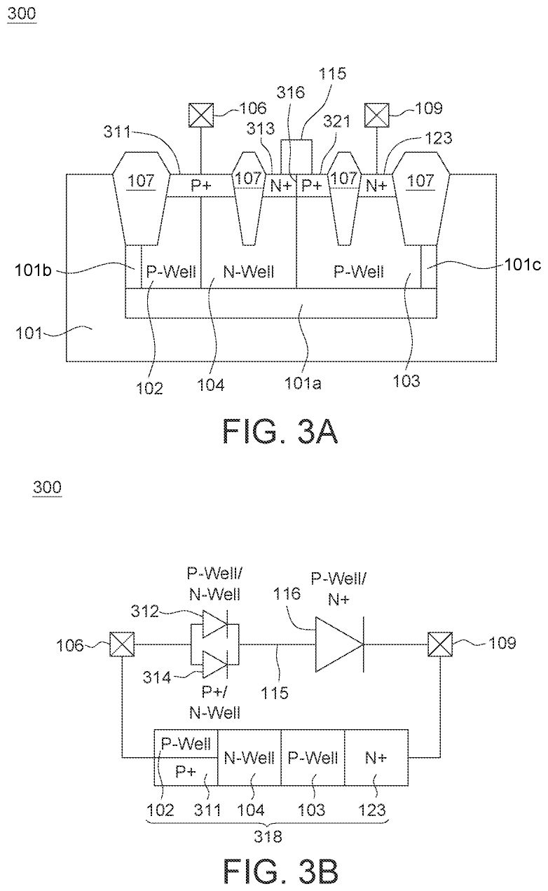

Please refer to FIGS. 3A and 3B, which respectively show a cross-sectional schematic diagram of an ESD device and a schematic diagram of its equivalent circuit according to another embodiment of the present invention. The structure of the ESD device 300 is analog to that of the ESD device 100 shown in FIG. 1A, except that a part of the first doping region 311 is disposed in the first well 102, another part of the first doping region 311 is disposed in the third well 104, and the second doping region 313 and the third doping region 321 are directly connected to each other to form a junction 316. The first doping region 311, the second doping region 313 and the third doping region 321 are analog to the first doping region 111, the second doping region 113 and the third doping region 121.

In the ESD device 300, there are two diodes connected in parallel, in which the first well 102 and the second well 103 are connected to form a diode 312, and the first doping region 311 and the third well 104 forms another diode 314, thereby the effective circuit path of electrostatic discharge is increased. In addition, after removing the isolation between the second well 103 and the third well 104, the second doping region 313 and the third doping region 321 are directly connected to each other to form a junction 316, so that the layout space occupied by the ESD device 300 can be reduced to reduce the overall layout size of the integrated circuit.

In addition, when ESD stress is applied to the internal circuit protected by the ESD device 300, the ESD current not only can flow into the diode string 312, 314 and 116, but also can respectively flow into the first well 102 and the third well 104 through the first doping regions 311 from the bonding pad 106, in which the first well 102, the third well 104, the second well 103 and the fourth doping area 123 constitute a first shunt of a parasitic silicon controlled rectifier 318, and the first doping region 311, the third well 104, the second well 103 and the fourth doping region 123 constitute a second shunt of the parasitic silicon controlled rectifier 318. The first shunt and the second shunt are connected in parallel, such that the effective circuit path for ESD is increased, and then, the ESD current is led to the bonding pad 109 through the fourth doping region 123.

Referring to FIG. 4, compared with the third embodiment, the comparative example does not have the third well 104 coupled between the first well 102 and the second well 103 and the second doping region 313 and the third doping region 321 are not connected to each other to form a junction 316, although a parasitic silicon controlled rectifier 418 (P+/N-well/P-well/N-well) can be formed in the semiconductor substrate of the comparative example, one of the diodes (P+/N-Well) is not the base-emitter of the NPN bipolar transistor (N-well/P-well/N-well) in the parasitic silicon controlled rectifier 418, when the diode string 414 is turned on, the parasitic silicon controlled rectifier 418 is unable to turn on normally. In this embodiment of the invention, a parasitic silicon controlled rectifier 318 having two shunting paths (P-well/N-well/P-well/N+ and P+/N-well/P-well/N+) is formed in the semiconductor substrate 101, and the parasitic silicon controlled rectifier 318 and the diode string 312, 314 and 116 are connected in parallel to provide the ESD device 300 with two or more ESD paths to improve the current shunting capability, such that the effective circuit path of electrostatic discharge increases, and the effective resistance of the ESD device 300 is reduced. There is no need to provide another ESD protection component that takes up a larger layout space so as to reduce the overall layout size of the integrated circuit.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electrostatic discharge (ESD) protection device, comprising:
a semiconductor substrate;
a first well having a first conductivity;
a second well having the first conductivity;
a third well having a second conductivity, wherein the first well, the second well and the third well are disposed in the semiconductor substrate, and the third well is directly coupled to the first well and the second well and disposed between the first well and the second well;
a first doping region having the first conductivity and disposed in the first well;
a second doping region having the second conductivity, disposed in the third well, and the first doping region and the second doping region are isolated from each other;
a third doping region having the first conductivity and disposed in the second well, wherein the second doping region is electrically coupled to the third doping region; and
a fourth doping region having the second conductivity, disposed in the second well and isolated from the third doping region;
wherein, the first well, the second well, the third well and the fourth doping region form a parasitic silicon controlled rectifier.

2. The ESD protection device according to claim 1, wherein the first doping region is an anode of the parasitic silicon controlled rectifier, and the fourth doping region is a cathode of the parasitic silicon controlled rectifier.

3. The ESD protection device according to claim 1, wherein the parasitic silicon controlled rectifier comprises a parasitic PNP bipolar transistor circuit formed by the first well, the third well, and the second well, and a parasitic NPN bipolar transistor circuit formed by the third well, the second well and the fourth doping region.

4. The ESD protection device according to claim 1, wherein the first well and the third well are directly connected and contact each other to form a diode, the second well and the fourth doping region are directly connected and contact each other to form another diode, and the two diodes form a diode string.

5. The ESD protection device according to claim 4, wherein the parasitic silicon controlled rectifier and the diode string are connected in parallel.

6. The ESD protection device according to claim 1, wherein a part of the first doping region is disposed in the first well, and another part of the first doping region is disposed in the third well.

7. The ESD protection device according to claim 6, wherein the first well, the second well, the third well, and the fourth doping region constitute a first shunt of the parasitic silicon controlled rectifier, and the first doping region, the third well, the second well, and the fourth doping region constitute a second shunt of the parasitic silicon controlled rectifier, and the first shunt and the second shunt are connected in parallel.

8. The ESD protection device according to claim 6, wherein the first well and the third well are coupled to form a diode, and the first doping region and the third well are coupled to form another diode, the two diodes are connected in parallel.

9. The ESD protection device according to claim 8, wherein the parasitic silicon controlled rectifier and the two diodes are connected in parallel.

10. The ESD protection device according to claim 1, wherein the second doping region and the third doping region are directly connected to form a junction.

11. An operation method of an electrostatic discharge (ESD) protection device, comprising:
providing an ESD protection device, which is electrically connected to an internal circuit, wherein the ESD protection device comprises a parasitic silicon controlled rectifier and a diode string connected to each other; and
when an ESD stress is applied to the internal circuit, the ESD protection device leads an ESD current from one bonding pad to another bonding pad.

12. The operation method according to claim 11, wherein the parasitic silicon controlled rectifier and the diode string are connected in parallel.

13. The operation method according to claim 11, wherein the diode string comprises two diodes connected in series.

14. The operation method according to claim 13, wherein the parasitic silicon controlled rectifier and the two diodes are connected in parallel.

15. The operation method according to claim 11, wherein the diode string comprises two diodes connected in parallel.

16. The operation method according to claim 15, wherein the parasitic silicon controlled rectifier and the two diodes are connected in parallel.
